(19) United States
(12) Patent Application Publication
(10) Pub. No.: US 2016/0183360 A1
(43) Pub. Date: Jun. 23, 2016

(54) PRINTED CIRCUIT BOARD AND ELECTRONIC DEVICE UTILIZING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: NIAN MIN, Wuhan (CN); HOU-YUAN CHOU, New Taipei (TW); BING CHEN, Wuhan (CN)

(21) Appl. No.: 14/690,033

(22) Filed: Apr. 17, 2015

(30) Foreign Application Priority Data
Dec. 17, 2014 (CN) 201410780234.2

(51) Int. Cl. H05K 1/02; H05K 1/11

(52) U.S. Cl. CPC H05K 1/0216; H05K 1/115

(57) ABSTRACT

A printed circuit board for an electronic device includes first and second sets of differential vias. Each set of differential vias comprises two vias. A first line segment couples two centres of the two vias of the first set of differential vias. A second line segment couples two centres of the two vias of the second set of differential vias. The first line segment is parallel to the second line segment, and is offset a first distance from the second line segment. A first perpendicular bisector of the first line segment is offset a second distance from a second perpendicular bisector of the second line segment. The second distance is between 45 mil and 55 mil. Therefore, the near end crosstalk and far end crosstalk of two couples of differential vias are minimum.

### FIELD

The subject matter herein generally relates to a printed circuit board and an electronic device utilizing the printed circuit board.

### BACKGROUND

With the rapid improvement in speed of switches in integrated circuits (ICs), the increasing density of signal lines of a PCB, and the decreasing size of the PCB, demand for better quality transmission characteristics of signals is growing.

### BRIEF DESCRIPTION OF THE DRAWINGS

Implementations of the present technology will now be described, by way of example only, with reference to the attached figures.

FIG. 1 is a diagrammatic view of an embodiment of an electronic device including a printed circuit board (PCB).

FIG. 2 is a graph illustrating a simulated near-end crosstalk performance for two adjacent couples of differential vias of the PCB of FIG. 1.

FIG. 3 is a graph illustrating a simulated far-end crosstalk performance for two adjacent couples of differential vias of the PCB of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

The disclosure will now be described in relation to a printed circuit board.

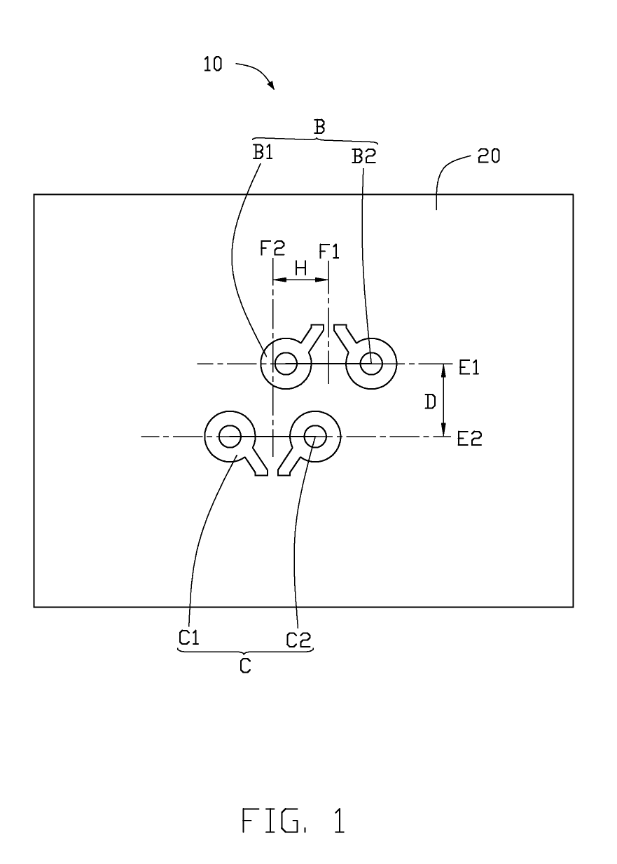

FIG. 1 illustrates a diagrammatic view of an embodiment of a printed circuit board (PCB) 20 applied in an electronic device 10. In the embodiment, the PCB 20 is a motherboard of a computer, and the electronic device 10 is a notebook computer or a desktop computer.

The PCB 20 includes a first couple of differential vias C and a second coupled of differential vias B. The first couple of differential vias C includes two vias C1, C2. The second couple of differential vias B includes two vias B1, B2. A line segment E1 couples the two centres of the vias C1, C2. A line segment E2 couples the two centres of the vias B1, B2, and is parallel to the line segment E1. Line F1 sands for a perpendicular bisector of the line segment E1. Line F2 stands for a perpendicular bisector of the line segment E2. The line segment E2 is non-collinear with the line segment E1, and is offset a first distance D from the line segment E1. The perpendicular bisector F1, F2 are offset from each other at a second distance H. In this embodiment, the second distance H is 45 mil-55 mil. Two two centres of the vias of each couple of differential vias are separated at a distance of 35 mil.

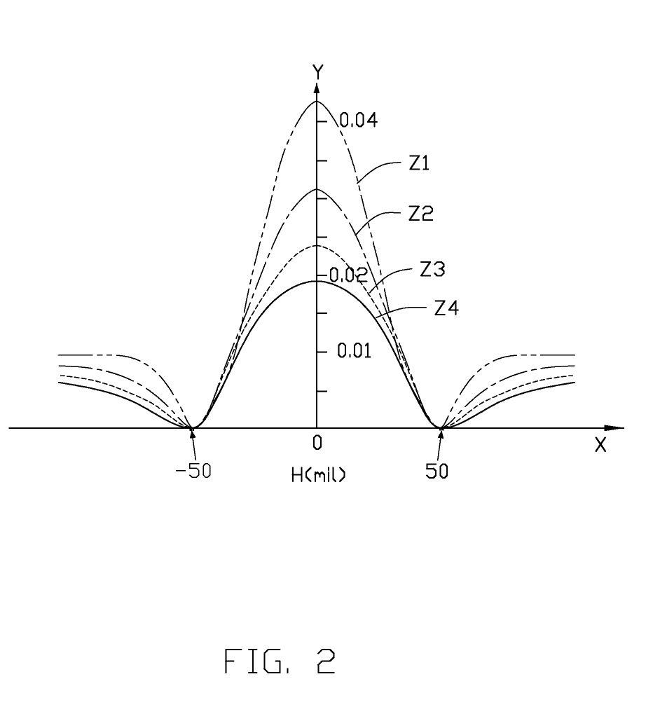

FIG. 2 is illustrates a curve Z1 representing a simulated near-end crosstalk performance for two adjacent couples of differential vias C, B of the PCB 20, when the first distance D is 35 mil. A curve Z2 representing a simulated near-end crosstalk performance for two adjacent couples of differential vias C, B of the PCB 20, when the first distance D is 40 mil. A curve Z3 representing a simulated near-end crosstalk performance for two adjacent couples of differential vias C, B of the PCB 20, when the first distance D is 45 mil. A curve Z4 representing a simulated near-end crosstalk performance for two adjacent couples of differential vias C, B of the PCB 20, when the first distance D is 50 mil. In addition, when the second distance H is between 45 mil-55 mil, the near end crosstalk of four curves Z1, Z2, Z3 and Z4 is minimum. Furthermore, when the second distance H is about 50 mil, the near end crosstalk of four curves Z1, Z2, Z3 and Z4 approaches zero. The near end crosstalk of four curves Z1, Z2, Z3 and Z4 is decreasing with an increasing of the first distance D.

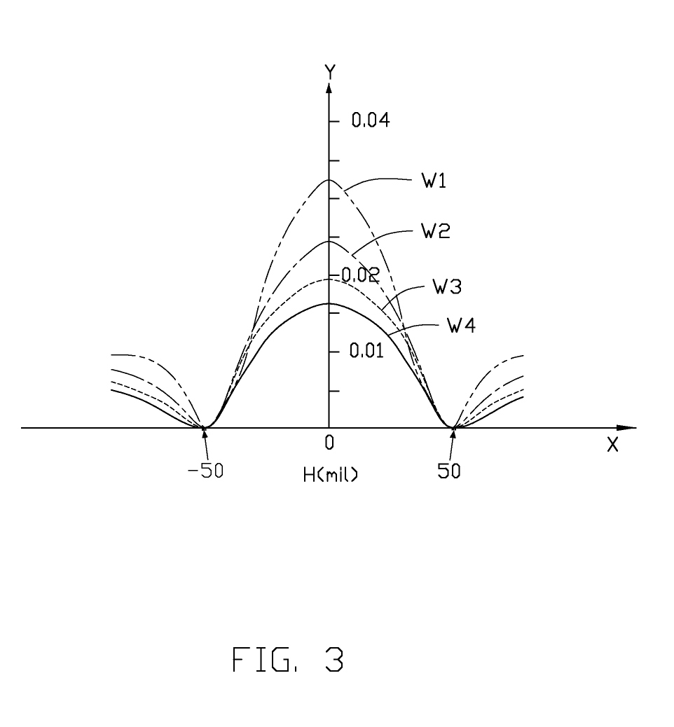

FIG. 3 illustrates a curve W1 representing a simulated far-end crosstalk performance for two adjacent couples of differential vias C, B of the PCB 20, when the first distance D is 35 mil. A curve W2 representing a simulated far-end crosstalk performance for two adjacent couples of differential vias C, B of the PCB 20, when the first distance D is 40 mil. A curve W3 representing a simulated far-end crosstalk performance for two adjacent couples of differential vias C, B of the PCB 20, when the first distance D is 45 mil. A curve W4 representing a simulated far-end crosstalk performance for two adjacent couples of differential vias C, B of the PCB 20, when the first distance D is 50 mil. In addition, when the second distance H is between 45 mil-55 mil, the far end crosstalk of four curves W1, W2, W3 and W4 is minimum. Furthermore, when the second distance H is about 50 mil, the far end crosstalk of four curves W1, W2, W3 and W4 approaches zero. The far end crosstalk of four curves W1, W2, W3 and W4 is decreasing with an increasing of the first distance D.

Therefore, when the second distance H is between 45 mil-55 mil, the near end crosstalk and far end crosstalk of two couples of differential vias C, B of the PCB 20 is minimum. If the PCB 20 includes a plurality of couples of differential vias, a position relationship of each two adjacent couples of differential vias is same as the two couples of differential vias C, B of the PCB 20.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A printed circuit board, comprising:
a first set of differential vias comprising:
a first differential via coupled with a second differential via;
a second set of differential vias comprising:
a third differential via coupled with a fourth differential via;
wherein a first line segment couples two centres of the first and second of the first set of differential vias, a second line segment couples two centres of the third and fourth of the second set of differential vias; the first line segment is parallel to the second line segment, and is offset a first distance from the second line segment; a first perpendicular bisector of the first line segment is offset a second distance from a second perpendicular bisector of the second line segment, and the second distance is between 45 mil and 55 mil.

2. The printed circuit board of claim 1, wherein the second distance is 50 mil.

3. The printed circuit board of claim 2, wherein the first distance is 35 mil, 40 mil, 45 mil or 50 mil.

4. The printed circuit board of claim 3, wherein two centres of the vias of each set of differential vias are separated at a distance of 35 mil.

5. An electronic device, comprising a printed circuit board, the printed circuit board comprising:
a first set of differential vias comprising:
a first differential via coupled with a second differential via;
a second set of differential vias comprising:
a third differential via coupled with a fourth differential via;
wherein a first line segment couples two centres of the first and second of the first set of differential vias, a second line segment couples two centres of the third and fourth of the second set of differential vias; the first line segment is parallel to the second line segment, and is offset a first distance from the second line segment; a first perpendicular bisector of the first line segment is offset a second distance from a second perpendicular bisector of the second line segment, and the second distance is between 45 mil and 55 mil.

6. The electronic device of claim 5, wherein the second distance is 50 mil.

7. The electronic device of claim 6, wherein the first distance is 35 mil, 40 mil, 45 mil or 50 mil.

8. The electronic device of claim 7, wherein two centres of the vias of each set of differential vias are separated at a distance of 35 mil.
